(19) United States
(12) Patent Application Publication
(10) Pub. No.: US 2016/0240523 A1
(43) Pub. Date: Aug. 18, 2016

(54) Method for Manufacturing Semiconductor Device, Sheet-Shaped Resin Composition, and Dicing Tape-Integrated Sheet-Shaped Resin Composition

(71) Applicant: NITTO DENKO CORPORATION, Ibaraki-shi, Osaka (JP)

(72) Inventors: Naohide Takamoto, Ibaraki-shi (JP); Hiroyuki Hanazono, Ibaraki-shi (JP); Akihiro Fukui, Ibaraki-shi (JP)

(21) Appl. No.: 15/031,219

(22) PCT Filed: Oct. 3, 2014
(86) PCT No.: PCT/JP2014/076561

§ 371 Date: Apr. 21, 2016

(30) Foreign Application Priority Data
Oct. 22, 2013 (JP) 2013-219399

(51) Int. Cl. H01L 25/00; H01L 21/768; H01L 21/3105; H01L 21/683; H01L 23/00; H01L 21/78; H01L 21/56

(52) U.S. Cl. CPC H01L 25/50; H01L 21/78; H01L 21/76897; H01L 21/561; H01L 21/6836; H01L 24/97; H01L 24/83; H01L 21/3105; H01L 2224/83048; H01L 2225/06579; H01L 2225/06541; H01L 2224/95001

(57) ABSTRACT

Provided is a method for manufacturing a semiconductor device, which can manufacture a semiconductor device at a high yield ratio by suppressing dissolution of a sheet-shaped resin composition when cleaning a wafer after peeling a supporting member from the wafer. The present invention provides a method for manufacturing a semiconductor device, the method including: a step A of preparing a wafer; a step B of pasting together a second main surface of the wafer and a supporting member including a support and a temporary fixing layer formed on the support with the temporary fixing layer interposed between the second main surface and the supporting member; a step C of preparing a laminate including a dicing tape and an ultraviolet curable sheet-shaped resin composition laminated on the dicing tape; a step D of pasting together a first main surface of the wafer and the sheet-shaped resin composition; a step E of peeling the supporting member from the wafer after the step D; a step F of cleaning the second main surface of the wafer after the step E; and a step S of irradiating a peripheral part of the sheet-shaped resin composition with ultraviolet light to cure the peripheral part after the step D and before the step F, the peripheral part not overlapping with the wafer in a plan view.

### TECHNICAL FIELD

The present invention relates to a method for manufacturing a semiconductor device, a sheet-shaped resin composition, and a dicing tape-integrated sheet-shaped resin composition.

### BACKGROUND ART

In recent years, a semiconductor production technique has been used in which thinner semiconductor chips were manufactured and these are laminated into a multilayer while being connected with a Through Silicon Via (TSV) to produce a semiconductor device. In order to realize this, a step is necessary of making a thinner wafer by grinding a non-circuit-forming surface (also referred to as a backside) of the wafer in which a semiconductor circuit is formed and forming electrodes including the TSV on the backside (for example, refer to Patent Document 1).

In this semiconductor production technique, the backside grinding is performed while a support is bonded to the wafer in order to make up for insufficiency of the strength caused by making the wafer thinner. When the through electrode is formed, a process at high temperature (for example, 250° C. or more) is included. Therefore, a material having heat resistance (for example, heat resistant glass) is used for the support.

On the other hand, a sheet-shaped resin composition has been known that is used in a flip-chip type semiconductor device in which a semiconductor chip is mounted by flip-chip bonding (flip-chip bonded) on a substrate, and used for sealing the interface between the semiconductor chip and the substrate (for example, refer to Patent Document 2).

FIGS. 8 to 11 are drawings for explaining one example of a conventional semiconductor device production method. As shown in FIG. 8, in the conventional semiconductor device production method, a wafer 100 with a support is prepared first which includes a wafer 100, a temporary fixing sheet 130, and a support 120 bonded to one side 110a of the wafer 110 on which a through electrode (not shown in the drawing) is formed with the temporary fixing sheet 130 interposed therebetween. For example, the wafer 100 with a support can be obtained with a step of bonding the circuit forming side of the wafer having a circuit forming side and a non-circuit-forming side to the support with a temporary fixing layer interposed therebetween, a step of grinding the non-circuit-forming side of the wafer that is bonded to the support, and a step of performing processes (for example, forming the TSV, forming an electrode, and forming a metal wiring) on the ground non-circuit-forming side of the wafer. The support is bonded to the wafer to secure the strength of the wafer upon and after grinding of the wafer. The step of performing processes described above includes processes at high temperature (for example, 250° C. or more). Because of that, a material having a certain level of strength and heat resistance (for example, a heat resistant glass) is used for the support.

Next, as shown in FIG. 9, a dicing tape-integrated sheet-shaped resin composition 140 is prepared which includes a dicing tape 150 and a sheet-shaped resin composition 160 laminated on the dicing tape 150. For example, the sheet-shaped resin composition disclosed in Patent Document 2 is used as the sheet-shaped resin composition 160.

Next, as shown in FIG. 10, the other side 110a of the wafer 100 with a support is pasted to the sheet-shaped resin composition 160 of the dicing tape-integrated sheet-shaped resin composition 140.

Next, as shown in FIG. 11, the support 120 is peeled together with a temporary fixing layer 130 from the wafer 110.

After that, the wafer 110 is diced together with the sheet-shaped resin composition 160 to form a chip with the sheet-shaped resin composition (not shown in the drawing). The chip with the sheet-shaped resin composition is pasted to a mounting substrate, the electrodes of the chip and the electrodes of the mounting substrate are bonded, and the space between the chip and the mounting substrate is sealed with the sheet-shaped composition.

With this, the chip in which the through electrode is formed is mounted to the mounting substrate, and a semiconductor device can be obtained in which the space between the chip and the mounting substrate is sealed with the sheet-shaped composition.

### PRIOR ART DOCUMENTS

### Patent Documents

Patent Document 1: JP-A-2012-12573

Patent Document 2: JP-B2-4438973

### SUMMARY OF THE INVENTION

### Problems to be Solved by the Invention

When the step of peeling the support 120 together with the temporary fixing layer 130 from the wafer 110 is performed in the method for manufacturing the semiconductor device, a part of the temporary fixing layer 130 may remain on the wafer 110. The left residue may cause defects in the subsequent step. The residue can be removed by cleaning the wafer.

However, when the peripheral part of the sheet-shaped resin composition 160 is exposed, the sheet-shaped resin composition 160 is also dissolved by the solvent (see FIG. 11). This may cause further contamination of the wafer, loss of a function as a sheet-shaped resin composition for sealing a space between the chip and the mounting substrate, and a decrease in a yield ratio.

The present invention has been made in view of the above-described problems, and an object thereof is to provide a method for manufacturing a semiconductor device, which can manufacture a semiconductor device at a high yield ratio by suppressing dissolution of a sheet-shaped resin composition when cleaning a wafer after peeling a supporting member from the wafer, a sheet-shaped resin composition suitable for the manufacturing method, and a dicing tape-integrated sheet-shaped resin composition.

### Means for Solving the Problems

The present inventors have found that the above-described problems can be solved by adopting the following configuration, and thus have completed the present invention.

That is, the present invention provides a method for manufacturing a semiconductor device including:

a step A of preparing a wafer having a first main surface having at least a connecting member formed thereon;

a step B of pasting together a second main surface opposite to the first main surface of the wafer and a supporting member including a support and a temporary fixing layer formed on the support with the temporary fixing layer interposed between the second main surface and the supporting member, to form a wafer with a supporting member;

a step C of preparing a dicing tape-integrated sheet-shaped resin composition including a dicing tape and an ultraviolet curable sheet-shaped resin composition laminated on the dicing tape;

a step D of pasting together the first main surface of the wafer of the wafer with a supporting member and the sheet-shaped resin composition of the dicing tape-integrated sheet-shaped resin composition;

a step E of peeling the supporting member from the wafer after the step D;

a step F of cleaning the second main surface of the wafer after the step E; and

a step S of irradiating a peripheral part of the sheet-shaped resin composition with ultraviolet light to cure the peripheral part after the step D and before the step F, the peripheral part not overlapping the wafer in plan view.

According to the manufacturing method, an ultraviolet curable sheet-shaped resin composition is used for the dicing tape-integrated sheet-shaped resin composition. The exposed peripheral part of the sheet-shaped resin composition is subjected to ultraviolet curing at any stage after the wafer with a supporting member and the dicing tape-integrated sheet-shaped resin composition are pasted together before the wafer is cleaned. In this manner, the semiconductor device can be manufactured at a high yield ratio by suppressing the dissolution of the sheet-shaped resin composition even if the wafer is cleaned to remove the residue of the sheet-shaped resin composition on the wafer.

In the manufacturing method, the peripheral part of the sheet-shaped resin composition is preferably irradiated with ultraviolet light from the wafer side in the step S. It is necessary to avoid the curing of a central part of the sheet-shaped resin composition overlapping with the wafer in a plan view by ultraviolet light irradiation in order to hold the wafer and a chip during the subsequent wafer dicing. Since the wafer serves as a masking for the central part of the sheet-shaped resin composition during the ultraviolet light irradiation when the peripheral part of the sheet-shaped resin composition is irradiated with ultraviolet light from the wafer side at this time, it is not necessary to mask the central part by separate means, and thereby the peripheral part can be irradiated with ultraviolet light to efficiently cure the peripheral part.

In the manufacturing method, the step S is preferably performed after the step D and before the step E. In this manner, the fixation of the temporary fixing layer to the sheet-shaped resin composition can be reduced.

Preferably, the manufacturing method further includes a step G of dicing the wafer together with the sheet-shaped resin composition after the step F, to obtain a chip with a sheet-shaped resin composition. As described above, the dissolution of the sheet-shaped resin composition is suppressed. Therefore, the sheet-shaped resin composition in the chip with a sheet-shaped resin composition obtained in the step F sufficiently functions as a sheet-shaped resin composition for sealing a space between a chip and a mounting substrate.

Preferably, the manufacturing method further includes a step H of disposing the chip with a sheet-shaped resin composition on a mounting substrate after the step G, and sealing a space between the chip and the mounting substrate with the sheet-shaped composition while bonding the connecting member included in the chip and an electrode included in the mounting substrate. As described above, the dissolution of the sheet-shaped resin composition is suppressed. Therefore, the yield ratio of the semiconductor device (the semiconductor device in which the space between the chip and the mounting substrate is sealed with the sheet-shaped composition) obtained in the step G can be improved.

In the manufacturing method, the step D is preferably performed under reduced pressure. When the step D is performed under reduced pressure, void generation in the interface between the wafer and the sheet-shaped resin composition can be suppressed when the wafer and the sheet-shaped resin composition are pasted together, and thereby a more reliable semiconductor device can be manufactured.

The present invention also includes a sheet-shaped resin composition used in the method for manufacturing a semiconductor device.

The present invention also includes a dicing tape-integrated sheet-shaped resin composition used in the method for manufacturing a semiconductor device. This configuration can further improve the productivity of the semiconductor device from the viewpoint of omitting the step of pasting together the dicing tape and the sheet-shaped resin composition since the dicing tape-integrated sheet-shaped resin composition is used.

### BRIEF DESCRIPTION OF THE DRAWINGS

FIG. 1 is schematic cross-sectional diagram for illustrating a method for manufacturing a semiconductor device according to an embodiment of the present invention.

FIG. 2 is schematic cross-sectional diagram for illustrating a method for manufacturing a semiconductor device according to an embodiment of the present invention.

FIG. 3 is schematic cross-sectional diagram for illustrating a method for manufacturing a semiconductor device according to an embodiment of the present invention.

FIG. 4 is schematic cross-sectional diagram for illustrating a method for manufacturing a semiconductor device according to an embodiment of the present invention.

FIG. 5 is schematic cross-sectional diagram for illustrating a method for manufacturing a semiconductor device according to an embodiment of the present invention.

FIG. 6 is schematic cross-sectional diagram for illustrating a method for manufacturing a semiconductor device according to an embodiment of the present invention.

FIG. 7 is schematic cross-sectional diagram for illustrating a method for manufacturing a semiconductor device according to an embodiment of the present invention.

FIG. 8 is a schematic cross-sectional drawing for explaining one example of a conventional method for manufacturing a semiconductor device.

FIG. 9 is a schematic cross-sectional drawing for explaining one example of a conventional method for manufacturing a semiconductor device.

FIG. 10 is a schematic cross-sectional drawing for explaining one example of a conventional method for manufacturing a semiconductor device.

FIG. 11 is a schematic cross-sectional drawing for explaining one example of a conventional method for manufacturing a semiconductor device.

### MODE FOR CARRYING OUT THE INVENTION

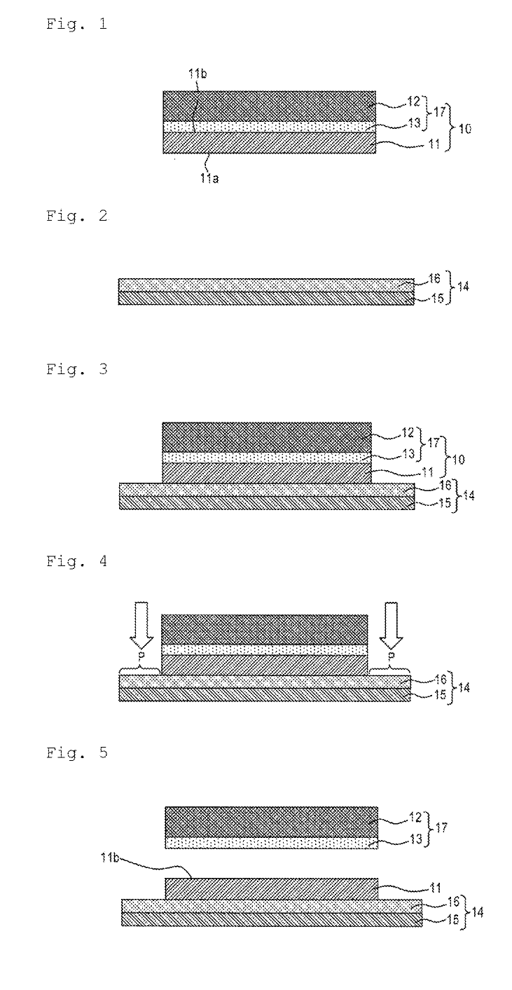

An embodiment of the present invention will be described below with reference to the drawings. The form illustrated in each of the drawings is not to scale, but is illustrated in a partially enlarged or reduced scale for the convenience of the description. FIGS. 1 to 7 are schematic cross-sectional diagrams for illustrating a method for manufacturing a semiconductor device according to an embodiment of the present invention.

A method for manufacturing a semiconductor device according to the present embodiment includes the following steps:

a step A of preparing a wafer having a first main surface having at least a connecting member formed thereon;

a step B of pasting together a second main surface opposite to the first main surface of the wafer and a supporting member including a support and a temporary fixing layer formed on the support with the temporary fixing layer interposed between the second main surface and the supporting member, to form a wafer with a supporting member;

a step C of preparing a dicing tape-integrated sheet-shaped resin composition including a dicing tape and an ultraviolet curable sheet-shaped resin composition laminated on the dicing tape;

a step D of pasting together the first main surface of the wafer of the wafer with—a supporting member and the sheet-shaped resin composition of the dicing tape-integrated sheet-shaped resin composition;

a step E of peeling the supporting member from the wafer after the step D; and

a step F of cleaning the first main surface of the wafer after the step E.

The manufacturing method further includes the following step:

a step S of irradiating a peripheral part of the sheet-shaped resin composition with ultraviolet light to cure the peripheral part after the step D and before the step F, the peripheral part not overlapping with the wafer in a plan view.

[Step A—Wafer Preparing Step]

In the step A, a wafer 11 is prepared which has a first main surface 11a having at least a connecting member (not shown) formed thereon. Examples of the wafer 11 include a silicon wafer, a germanium wafer, a gallium-arsenide wafer, a gallium-phosphide wafer, and a gallium-aluminum arsenide wafer.

The material of the connecting member such as a bump or a conductive material is not particularly limited, and examples thereof include solders (alloys) such as a tin-lead metal material, a tin-silver metal material, a tin-silver-copper metal material, a tin-zinc metal material and a tin-zinc-bismuth metal material; a gold metal material; and a copper metal material. The height of the connecting member is also determined according to an application, and is generally about 15 to 100 μm. Of course, the height of each connecting member in the wafer 11 may be the same or different. When the connecting members are formed on both surfaces of the wafer, the connecting members may or may not be electrically connected to each other. Examples of electrical connection between the connecting members include connection through a via, which is called a through silicon via (TSV) type.

[Step B—Wafer with—a Supporting member Preparing Step]

In the wafer with—a supporting member preparing step (step B), a second main surface 11b opposite to the first main surface 11a of the wafer 11 and a supporting member 17 including a support 12 and a temporary fixing layer 13 formed on the support 12 are pasted together with the temporary fixing layer 13 interposed between the second main surface 11b and the supporting member 17, to form a wafer 10 with—a supporting member (see FIG. 1). For example, the wafer 10 with a supporting member can be formed according to a procedure including a step of bonding a circuit-forming surface of the wafer 11 having the circuit-forming surface and a non-circuit-forming surface (back surface) to the temporary fixing layer 13 of the supporting member 17 (supporting member bonding step), a step of grinding the non-circuit-forming surface of the wafer which is bonded to the support 12 (wafer back surface grinding step), and a step of performing processing (for example, formation of TSV (through silicon via), formation of electrode, and formation of metal wiring) on the ground non-circuit-forming surface of the wafer (non-circuit-forming surface processing step). More specifically, examples of the step of performing processes on the non-circuit-forming surface of the wafer are conventionally known processes such as metal sputtering for forming an electrode, etc., wet etching for etching the metal sputtering layer, pattern formation by applying, exposing, and developing resist to produce a mask for forming the metal wiring, peeling of the resist, dry etching, formation of metal plating, silicon etching for forming the TSV, and formation of an oxide film on the surface of silicon. The support 12 is bonded to the wafer 11 to secure the strength of the wafer when the wafer is ground. The step of performing processes described above includes processes at high temperature (for example, 250° C. or more). Because of that, a material having a certain level of strength and heat resistance (for example, a heat resistant glass) is used for the support 12.

(Support)

A material having a certain level of strength and heat resistance can be used for the support 12. Examples of the support 12 include heat resistant glass, heat resistant engineering plastic, and a wafer (for example, the wafer 11).

(Temporary Fixing Layer)

A pressure-sensitive adhesive composition constituting the temporary fixing layer 13 is not particularly limited as long as the pressure-sensitive adhesive composition is not peeled from the support 11 and the wafer 12 when performing the step of grinding the back surface of the wafer and the step of performing processing on the non-circuit-forming surface, and can separate the supporting member 17 from the wafer 11 in the step E (supporting member peeling step). Heretofore known pressure-sensitive adhesive compositions can be used. Examples of the formation material for forming the temporary fixing layer 13 include a solvent soluble pressure-sensitive adhesive composition (the temporary fixing layer is dissolved by a solvent, to peel the layer), an ultraviolet curable pressure-sensitive adhesive composition (the temporary fixing layer is irradiated with ultraviolet light to cure the temporary fixing layer, thereby reducing a pressure-sensitive adhesive strength to peel the layer), a thermosetting pressure-sensitive adhesive composition (the temporary fixing layer is thermally cured to reduce a pressure-sensitive adhesive strength, thereby peeling the layer), a thermal foaming peeling pressure-sensitive adhesive composition (the temporary fixing layer is thermally foamed to produce surface unevenness, and a pressure-sensitive adhesive strength is reduced by the surface unevenness to peel the layer), a laser firing peeling pressure-sensitive adhesive composition (the temporary fixing layer is fired by laser to reduce a pressure-sensitive adhesive strength, thereby peeling the layer), and a multistage pressure-sensitive adhesive strength composition for applying strong pressure-sensitive adhesion to the peripheral part of the temporary fixing layer and applying weak pressure-sensitive adhesion to the inside of the peripheral part to block the pressure-sensitive adhesive strength of the peripheral part during peeling. Specific examples of resins contained in these compositions include a polyimide resin, a silicone resin, an aliphatic olefin resin, a hydrogenated styrene thermoplastic elastomer, and an acrylic resin.

The polyimide resin can be generally obtained by imidization (dehydration condensation) of polyamic acid which is a precursor of the polyimide resin. Examples of the method of imidizing polyamic acid include conventionally known heating imidization, azeotropic dehydration, and chemical imidization. Among these, the heating imidization is preferable. When the heating imidization is adopted, the heating treatment is preferably performed under an inert atmosphere such as a nitrogen atmosphere or a vacuum to prevent deterioration of the polyimide resin by oxidation.

The polyamic acid can be obtained by preparing acid anhydride and diamine in a solvent that is appropriately selected essentially in equi-molar ratio and making them react.

The polyimide resin is not especially limited. However, a polyimide resin can be used having a constituting unit derived from a diamine having an ether structure. The diamine having an ether structure is not especially limited as long as the diamine has an ether structure and is a compound at least having two ends having an amine structure. Among diamines having the ether structure, a diamine having a glycol skeleton is preferable.

Examples of the diamine having a glycol skeleton are diamines having a polypropylene glycol structure and having one amino group in each of the ends, diamines having a polyethylene glycol structure and having one amino group in each of the ends, diamines having a polytetramethylene glycol structure and having one amino group in each of the ends, and diamines having a plurality of these glycol structures and having one amino in each of the ends.

The molecular weight of the diamine having an ether structure is preferably in a range of 100 to 5,000, and more preferably 150 to 4,800. When the molecular weight of the diamine having an ether structure is in a range of 100 to 5,000, the temporary fixing layer 13 can be easily obtained having large adhering strength at low temperature and that exhibits peelability at high temperature.

In the formation of the polyimide resin, other types of diamine having no ether structure may be used together besides diamines having an ether structure. Examples of the other types of diamine having no ether structure are aliphatic diamines and aromatic diamines. When the other types of diamine having no ether structure are used together, the adhesion with the adherend can be controlled. The mixing ratio of diamine having an ether structure and diamine having no ether structure in molar ratio is preferably 100:0 to 20:80, and more preferably 99:1 to 30:70.

Examples of the aliphatic diamine include ethylene diamine, hexamethylene diamine, 1,8-diaminooctane, 1,10-diaminodecane, 1,12-diaminododecane, 4,9-dioxa-1,12-diaminododecane, and 1,3-bis(3-aminopropyl)-1,1,3,3-tetramethyldisiloxane(α,ω-bisamin opropyltetramethyldisiloxane). The molecular weight of the aliphatic diamine is normally 50 to 1,000,000, and preferably 100 to 30,000.

Examples of the aromatic diamine include 4,4′-diaminodiphenylether, 3,4′-diaminodiphenylether, 3,3′-diaminodiphenylether, m-phenylenediamine, p-phenylenediamine, 4,4′-diaminodiphenylpropane, 3,3′-diaminodiphenylmethane, 4,4′-diaminodiphenylsulfide, 3,3′-diaminodiphenylsulfide, 4,4′-diaminodiphenylsulfone, 3,3′-diaminodiphenylsulfone, 1,4-bis(4-aminophenoxy)benzene, 1,3-bis(4-aminophenoxy)benzene, 1,3-bis(3-aminophenoxy)benzene, 1,3-bis(4-aminophenoxy)-2,2-dimethylpropane, and 4,4′-diaminobenzophenone. The molecular weight of the aromatic diamine is normally 50 to 1,000, and preferably 100 to 500. In the present description, the molecular weight is measured with GPC (Gel Permeation Chromatography) and the value is expressed in terms of polystyrene (weight average molecular weight).

Examples of the acid anhydride include 3,3′,4,4′-biphenyltetracarboxylic dianhydride, 2,2′,3,3′-biphenyltetracarboxylic dianhydride, 3,3′,4,4′-benzophenonetetracarboxylic dianhydride, 2,2′,3,3′-benzophenonetetracarboxylic dianhydride, 4,4′-oxydiphthalic dianhydride, 2,2-bis(2,3-dicarboxyphenyl)hexafluoropropane dianhydride, 2,2-bis(3,4-dicarboxyphenyl)hexafluoropropane dianhydride (6FDA), bis(2,3-dicarboxyphenyl)methane dianhydride, bis(3,4-dicarboxyphenyl)methane dianhydride, bis(2,3-dicarboxyphenyl)sulfone dianhydride, bis(3,4-dicarboxyphenyl)sulfone dianhydride, pyromellitic dianhydride, and ethyleneglycol bistrimellitic dianhydride. These may be used either alone or in combination of two or more types.

Examples of the solvent that is used in the reaction of the acid anhydride and the diamine include N,N-dimethylacetamide, N-methyl-2-pyrrolidone, N,N-dimethylformamide, and cyclopentanone. These may be used either alone or in combination of two or more types. A nonpolar solvent such as toluene and xylene may be appropriately mixed to adjust the solubility of the raw materials and the resins.

When the polyimide resin having a constituting unit derived from a diamine having an ether structure is used for the temporary fixing layer 13, the weight reduction percentage of the temporary fixing layer 13 after the temporary fixing layer 13 is soaked in N-methyl-2-pyrrolidone (NMP) at 50° C. for 60 seconds and dried at 150° C. for 30 minutes is preferably 1.0% by weight or more, more preferably 1.2% by weight or more, and further preferably 1.3% by weight or more. The larger the weight reduction percentage is, the more preferable it is. For example, the weight reduction percentage is 50% by weight or less or 30% by weight or less. When the weight reduction percentage of the temporary fixing layer 13 after the temporary fixing layer 13 is soaked in N-methyl-2-pyrrolidone (NMP) at 50° C. for 60 seconds and dried at 150° C. for 30 minutes is 1.0% by weight or more, the temporary fixing layer 13 dissolves into N-methyl-2-pyrrolidone, and it is considered that the weight was reduced sufficiently. As a result, the temporary fixing layer 13 can be easily peeled off by N-methyl-2-pyrrolidone. The weight reduction percentage of the temporary fixing layer 13 can be controlled by the solubility of the raw materials to NMP. That is, the higher the solubility of the selected raw materials to NMP is, the higher the solubility becomes of the temporary fixing layer 13 that is obtained by using the raw materials to NMP.

Examples of the silicone resin include a peroxide crosslinked silicone pressure-sensitive adhesive, an addition reaction-type silicone pressure-sensitive adhesive, a dehydrogenation reaction-type silicone pressure-sensitive adhesive, and a moisture curable silicone pressure-sensitive adhesive. These silicone resins may be used either alone or in combination of two or more types. These silicone resins are superior in having high heat resistance. Among these silicone resins, the addition reaction-type silicone resin is preferable because such resin has less impurity.

When the silicon resin is used for the temporary fixing layer 13, the temporary fixing layer 13 may contain other additives as necessary. Examples of the other additives include a flame retardant, a silane coupling agent, and an ion trapping agent. Examples of the flame retardant include antimony trioxide, antimony pentoxide, and a brominated epoxy resin. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. Examples of the ion trapping agent include hydrotalcites and bismuth hydroxide. These additives may be used either alone or in combination of two or more types.

The acrylic resin is not especially limited. However, an example includes a polymer (an acrylic copolymer) having one type or two types or more of acrylate or methacrylate having a straight chain alkyl group or a branched alkyl group having 30 carbons or less, especially 4 to 18 carbons as a component. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and a dodecyl group.

Other monomers that form the polymer are not especially limited. However, examples include a monomer containing a carboxyl group such as acrylic acid, methacrylic acid, carboxyethylacrylate, carboxypentylacrylate, itaconic acid, maleic acid, fumaric acid, and crotonic acid; an acid anhydride monomer such as maleic anhydride and itaconic anhydride; a monomer containing a hydroxyl group such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxoctyl(meth)acrylate, 10-hydroxydecyl(meth)acrylate, 12-hydroxylauryl(meth)acrylate, and (4-hydroxymethylcyclohexyl)-methylacrylate; a monomer containing sulfonic acid group such as styrenesulfonic acid, allylsulfonic acid, 2-(meth)acrylamide-2-methylpropanesulfonic acid, (meth)acrylamidepropane sulfonic acid, sulfopropyl(meth)acrylate, and (meth)acryloyloxynaphthalenesulfonic acid; and a monomer containing a phosphate group such as 2-hydroxyehylacryloylphosphate.

The temporary fixing layer 13 can be produced as follows for example. First, a resin composition solution for forming the temporary fixing layer (a solution containing the polyamic acid when the temporary fixing layer 13 is formed with a polyimide resin) is produced. Next, the solution is applied on a base to form a coating film having a prescribed thickness, and the coating film is dried under a prescribed condition. Examples of the base include SUS304; 6-4 alloy; a metal foil such as an aluminum foil, a copper foil, and a Ni foil; polyethyleneterephthalate (PET); polyethylene; polypropylene; and a plastic film and paper in which the surface is coated with a release agent such as a fluorine release agent and a long chain alkylacrylate release agent. The applying method is not especially limited. However, examples include roll coating, screen coating, gravure coating, and spin coating. For the drying condition, for example, the drying temperature is 50° C. to 150° C. and the drying time is 3 minutes to 30 minutes. With this, the temporary fixing layer 13 according to the present embodiment can be obtained.

The wafer 10 with a supporting member in which the wafer 11 and the supporting member 17 are bonded with the temporary fixing layer 13 interposed therebetween can be produced by transferring the temporary fixing layer 13 to the support 12 and pasting the wafer 11. Or the wafer 10 with a support can be produced by transferring the temporary fixing layer 13 to the wafer 11 and pasting the support 12. Further, the wafer 10 with a support may be produced by directly applying the resin composition solution for forming the temporary fixing layer to the support 12 to form a coating film, drying the coating film under a prescribed condition to form the temporary fixing layer 13, and pasting the wafer 11. Or the wafer 10 with a support may be produced by directly applying the resin composition solution for forming the temporary fixing layer to the wafer 11 to forma coating film, drying the coating film under a prescribed condition to form the temporary fixing layer 13, and pasting the support 12.

[Step C—Dicing Tape-Integrated Sheet-shaped Resin Composition Preparing Step]

Next, in the dicing tape-integrated sheet-shaped resin composition preparing step (step C), a dicing tape-integrated sheet-shaped resin composition 14 is prepared which includes a dicing tape 15 and an ultraviolet curable sheet-shaped resin composition 16 laminated on the dicing tape 15 (see FIG. 2). The shape of the sheet-shaped resin composition 16 in a plan view is not particularly limited, and the shape may be circular, rectangular or the like. The size and shape of the sheet-shaped resin composition 16 are not particularly limited. For example, the shape of the sheet-shaped resin composition 16 is preferably a circular shape larger in diameter than the wafer 11 (for example, the diameter of the sheet-shaped resin composition 16 is 300 mm) when the wafer 11 has a circular shape in a plan view (for example, the diameter of the wafer 11 is 290 mm). In this case, the wafer 11 and the sheet-shaped resin composition 16 are preferably laminated so that the centers are aligned.

(Dicing Tape)

The dicing tape 15 is configured with a pressure-sensitive adhesive layer formed on a base. The base can be used as abase support of the pressure-sensitive adhesive layer, etc. Examples of the base include thin sheets of a paper base such as paper; a fiber base such as cloth, nonwoven cloth, felt, and net; a metal base such as a metal foil and a metal plate; a plastic base such as a plastic film; a rubber base such as a rubber sheet; a foaming body such as a foaming sheet; and a laminate of these (for example, a laminate of the plastic base and other bases and a laminate of the plastic films). The plastic base can be suitably used as the base of the present invention. Examples of the material for the plastic base include an olefin resin such as polyethylene (PE), polypropylene (PP) and an ethylene-propylene copolymer; a copolymer having ethylene as a monomer component such as an ethylene-vinylacetate copolymer (EVA), an ionomer resin, an ethylene-(meth)acrylic acid copolymer, and an ethylene-(meth)acrylate (random, alternating) copolymer; polyester such as polyethyleneterephthalate (PET), polyethylenenaphthalate (PEN), and polybutyleneterephthalate (PBT); an acrylic resin; polyvinylchloride (PVC); polyurethane; polycarbonate; polyphenylenesulfide (PPS); an amide resin such as polyamide (nylon) and fully aromatic polyamide (aramid); polyetheretherketone (PEEK); polyimide; ABS (an acrylonitrile-butadiene-styrene copolymer); a cellulose resin; a silicone resin; and a fluorine resin.

An example of the material of the base is a polymer such as a crosslinked body of the above-described resin. The plastic film may be used as being non-stretched or as being uniaxially stretched or biaxially stretched as necessary. With the resin sheet in which a heat shrinking property is given by the stretching treatment, etc., the contact area of the pressure-sensitive adhesive layer and the sheet-shaped resin composition 16 is decreased by thermally shrinking the base after dicing to make the collection of semiconductor elements easy.

In order to improve the tackiness, the holding property, etc. with the adjacent layer, the surface of the base can be treated with a traditional surface treatment, for example, a chemical treatment or a physical treatment such as a chromic acid treatment, ozone exposure, flame exposure, high pressure electric shock exposure, and an ionized radiation treatment; and a coating treatment with a primer (for example, a pressure-sensitive adhesive substance described later).

The same types or different types of the base can be appropriately selected and used, and several types can be blended and used for the base as necessary. In order to give the antistatic performance to the base, a vapor deposition layer of a conductive substance having a thickness of about 30 Å to 500 Å and consisting of metal, alloy, oxide of these, or the like can be provided on the base. The base may be a single layer or a multilayer of two types or more.

The thickness of the base (a total thickness when the base is a laminate) is not especially limited. However, the thickness can be appropriately selected depending on the strength, the flexibility, the purpose of use, etc. For example, the thickness of the base is generally 1,000 μm or less (for example, 1 μm to 1,000 μm), preferably 10 μm to 500 μm, more preferably 20 μm to 300 μm, and especially preferably 30 μm to 200 μm. However, the thickness is not limited to these ranges.

The base may contain various types of additives (a coloring agent, a filler, a plasticizer, an antiaging agent, an antioxidant, a surfactant, a flame retardant, etc.) without losing the effect, etc. of the present invention.

The pressure-sensitive adhesive layer is formed with the pressure-sensitive adhesive, and has adherability. The pressure-sensitive adhesive is not especially limited, and can be appropriately selected from the known pressure-sensitive adhesives. Specifically, a pressure-sensitive adhesive having the characteristics described above can be selected from known pressure-sensitive adhesives such as an acrylic pressure-sensitive adhesive, a rubber pressure-sensitive adhesive, a vinylalkylether pressure-sensitive adhesive, a silicone pressure-sensitive adhesive, a polyester pressure-sensitive adhesive, a polyamide pressure-sensitive adhesive, an urethane pressure-sensitive adhesive, a fluorine pressure-sensitive adhesive, a styrene-diene block copolymer pressure-sensitive adhesive, and a creep property-modified pressure-sensitive adhesive in which a thermally melting resin having a melting point of 200° C. or less is added to the above pressure-sensitive adhesive (for example, refer to JP-A-56-61468, JP-A-61-174857, JP-A-63-17981, JP-A-56-13040, etc.). In addition, a radiation curing pressure-sensitive adhesive (or an energy ray curing pressure-sensitive adhesive) or a thermoexpandable pressure-sensitive adhesive may be used. These pressure-sensitive adhesives may be used either alone or in combination of two or more types.

The acrylic pressure-sensitive adhesive and the rubber pressure-sensitive adhesive can be suitably used as the pressure-sensitive adhesive, and the acrylic pressure-sensitive adhesive is especially suitable. An example of the acrylic pressure-sensitive adhesive includes an acrylic pressure-sensitive adhesive having an acrylic polymer (a single polymer or a copolymer) as the base polymer, in which one type or two or more types of alkyl(meth)acrylate is used as the monomer component.

Examples of the alkyl(meth)acrylate in the acrylic pressure-sensitive adhesive include methyl(meth)acrylate, ethyl(meth)acrylate, propyl(meth)acrylate, isopropyl(meth)acrylate, butyl(meth)acrylate, isobutyl(meth)acrylate, s-butyl(meth)acrylate, t-butyl(meth)acrylate, pentyl(meth)acrylate, hexyl(meth)acrylate, heptyl(meth)acrylate, octyl(meth)acrylate, 2-ethylhexyl(meth)acrylate, isooctyl(meth)acrylate, nonyl(meth)acrylate, isononyl(meth)acrylate, decyl(meth)acrylate, isodecyl(meth)acrylate, undecyl(meth)acrylate, dodecyl(meth)acrylate, tridecyl(meth)acrylate, tetradecyl(meth)acrylate, pentadecyl(meth)acrylate, hexadecyl(meth)acrylate, heptadecyl(meth)acrylate, octadecyl(meth)acrylate, nonadecyl(meth)acrylate, and eicosyl(meth)acrylate. The alkyl(meth)acrylate preferably has an alkyl group having 7 to 18 carbon atoms. The alkyl group of the alkyl(meth)acrylate may be either of a straight chain or a branched chain.

The acrylic polymer may contain a unit corresponding to other monomer components (copolymerizable monomer component) that are copolymerizable with the alkyl(meth)acrylate as necessary for the purpose of modifying the cohesion, the heat resistance, the crosslinking property, etc. Examples of the copolymerizable monomer components include a monomer containing a carboxyl group such as (meth)acrylic acid (acrylic acid, methacrylic acid), carboxyethylacrylate, carboxypentylacrylate, itaconic acid, maleic acid, fumaric acid, and crotonic acid; a monomer containing an acid anhydride such as maleic anhydride and itaconic anhydride; a monomer containing a hydroxyl group such as hydroxyethyl(meth)acrylate, hydroxypropyl(meth)acrylate, hydroxybutyl(meth)acrylate, hydroxyhexyl(meth)acrylate, hydroxyoctyl(meth)acrylate, hydroxydecyl(meth)acrylate, hydroxylauryl(meth)acrylate, and (4-hydroxymethylcyclohexyl)methylmethacrylate; a monomer containing a sulfonic acid group such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalene sulfonic acid; a monomer containing a phosphoric acid group such as 2-hydroxyethylacryloylphosphate; an (N-substituted)amide monomer such as (meth)acrylamide, N,N-dimethyl(meth)acrylamide, N-butyl(meth)acrylamide, N-methylol(meth)acrylamide, and N-methylolpropane(meth)acrylamide; an aminoalkyl(meth)acrylate monomer such as aminoethyl(meth)acrylate, N,N-dimethylaminoethyl(meth)acrylate, and t-butylaminoethyl(meth)acrylate; an alkoxyalkyl(meth)acrylate monomer such as methoxyethyl(meth)acrylate and ethoxyethyl(meth)acrylate; a cyanoacrylate monomer such as acrylonitrile and methacrylonitrile; an acrylic monomer containing an epoxy group such as glycidyl(meth)acrylate; a styrene monomer such as styrene and α-methylstyrene; a vinylester monomer such as vinylacetate and vinylpropionate; an olefin monomer such as isoprene, butadiene, and isobutylene; a vinylether monomer such as vinylether; a monomer containing nitrogen such as N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, N-vinylcarboxylic acid amide, and N-vinylcaprolactam; a maleimide monomer such as N-cyclohexylmaleimide, N-isopropylmaleimide, N-laurylmaleimide, and N-phenylmaleimide; an itaconimide monomer such as N-methylitaconimide, N-ethylitaconimide, N-butylitaconimide, N-octylitaconimide, N-2-ethylhexylitaconimide, N-cyclohexylitaconimide, and N-laurylitaconimide; a succinimide monomer such as N-(meth)acryloyloxymethylene succinimide, N-(meth)acryloyl-6-oxyhexamethylene succinimide, and N-(meth)acryloyl-8-oxyoctamethylene succinimide; a glycol acrylester monomer such as polyethyleneglycol(meth)acrylate, polypropyleneglycol(meth)acrylate, methoxyethyleneglycol(meth)acrylate and methoxypropyleneglycol(meth)acrylate; an acrylic ester monomer having a heterocyclic ring, a halogen atom, a silicon atom, etc. such as tetrahydrofurfuryl(meth)acrylate, fluorine(meth)acrylate, and silicone(meth)acrylate; and a multifunctional monomer such a hexanediol di(meth)acrylate, (poly)ethyleneglycol di(meth)acrylate, (poly) propyleneglycol di(meth)acrylate, neopentylglycol di(meth)acrylate, pentaerythritol di(meth)acrylate, trimethylolpropane tri(meth)acrylate, pentaerythritol tri(meth)acrylate, dipentaerythritol hexa(meth)acrylate, epoxyacrylate, polyesteracrylate, urethaneacrylate, divinylbenzene, butyl di(meth)acrylate, and hexyl di(meth)acrylate. One type or two types or more of these copolymerizable monomer components can be used.

When a radiation curing pressure-sensitive adhesive (or an energy ray curing pressure-sensitive adhesive) is used as the pressure-sensitive adhesive, examples of the radiation curing pressure-sensitive adhesive (composition) include an intrinsic radiation curing pressure-sensitive adhesive in which a polymer having a radical reactive carbon-carbon double bond in the side chain or the main chain, or at the ends of the main chain of the polymer is used as the base polymer, and a radiation curing pressure-sensitive adhesive in which a monomer component or oligomer component that are curable by ultraviolet light are compounded in the pressure-sensitive adhesive. When a thermoexpandable pressure-sensitive adhesive is used as the pressure-sensitive adhesive, an example of the thermoexpandable pressure-sensitive adhesive includes a thermoexpandable pressure-sensitive adhesive containing a pressure-sensitive adhesive and a foaming agent (especially, thermoexpandable microspheres).

In the present invention, the pressure-sensitive adhesive may contain various types of additives (for example, a tackifying agent, a coloring agent, a thickening agent, an extender, a filler, a plasticizer, an antiaging agent, an antioxidant, a surfactant, a crosslinking agent, etc.) without losing the effect, etc. of the first part of the present invention.

The crosslinking agent is not especially limited, and a known crosslinking agent can be used. Specific examples of the crosslinking agent include an isocyanate crosslinking agent, an epoxy crosslinking agent, a melamine crosslinking agent, a peroxide crosslinking agent, a urea crosslinking agent, a metal alkoxide crosslinking agent, a metal chelate crosslinking agent, a metal salt crosslinking agent, a carbodiimide crosslinking agent, an oxazoline crosslinking agent, an aziridine crosslinking agent, and an amine crosslinking agent. The isocyanate crosslinking agent and the epoxy crosslinking agent are preferable. The crosslinking agents may be used either alone or in combination of two or more types. The use amount of the crosslinking agent is not especially limited.

Examples of the isocyanate crosslinking agent include lower aliphatic polyisocyanate such as 1,2-ethylene diisocyanate, 1,4-butylene diisocyanate, and 1,6-hexamethylene diisocyanate; alicyclic polyisocyanate such as cyclopentylene diisocyanate, cyclohexylene diisocyanate, isophorone diisocyanate, hydrogenated tolylene diisocyanate, and hydrogenated xylene diisocyanate; and aromatic polyisocyanate such as 2,4-tolylene diisocyanate, 2,6-tolylene diisocyanate, 4,4′-diphenylmethane diisocyanate, and xylylene diisocyanate. Besides these, a trimethylolpropane/tolylene diisocyanate trimer adduct [trade name “Coronate L” manufactured by Nippon Polyurethane Industry Co., Ltd.], a trimethylolpropane/hexamethylene diisocyanate trimer adduct [trade name “Coronate HL” manufactured by Nippon Polyurethane Industry Co., Ltd.], etc. can be used. Examples of the epoxy crosslinking agent include N,N,N′N′-tetraglycidyl-m-xylenediamine, diglycidylaniline, 1,3-bis(N,N-glycidylaminomethyl)cyclohexane, 1,6-hexanedioldiglycidylether, neopentylglycol diglycidylether, ethylenglycol diglycidylether, propyleneglycol diglycidylether, polyethylene glycol diglycidylether, polypropyleneglycol diglycidylether, sorbitol polyglycidylether, glycerol polyglycidylether, pentaerythritol polyglycidylether, polyglycerol polyglycidylether, sorbitan polyglycidylether, trimethylolpropane polyglycidylether, adipic diglycidylester, o-phthalic diglycidylester, triglycidyl-tris(2-hydroxyethyl)isocyanurate, resorcin diglycidylether, bisphenol-S-diglycidylether, and an epoxy resin having two or more epoxy groups in the molecule.

In the present invention, a crosslinking treatment can be performed by irradiating with an electron beam, ultraviolet light, etc. in place of using the crosslinking agent or while using the crosslinking agent.

The pressure-sensitive adhesive is mixed with a solvent, other additives, etc. as necessary, and can be formed into a sheet-shaped layer with a traditional method to form the pressure-sensitive adhesive layer. Specific examples of forming the pressure-sensitive adhesive layer include a method of applying the mixture containing the pressure-sensitive adhesive and the solvent and other additives as necessary on the base and a method of applying the mixture on an appropriate separator (such as release paper) to form a pressure-sensitive adhesive layer and transferring this to the base.

The thickness of the pressure-sensitive adhesive layer is not especially limited. However, the thickness is, for example, 5 μm to 300 μm (preferably 5 μm to 200 μm, more preferably 5 μm to 100 μm, and especially preferably 7 μm to 50 μm). When the thickness of the pressure-sensitive adhesive layer is within this range, a reasonable adhesive power can be exhibited. The pressure-sensitive adhesive layer may be either of a single layer or a multilayer.

(Sheet-Shaped Resin Composition)

The sheet-shaped resin composition 16 has ultraviolet curability, and has a function of sealing a space between a chip 20 (see FIG. 7) which is formed by dicing the wafer 11 and a mounting substrate 22 (see FIG. 7). The ultraviolet curability can be applied to the sheet-shaped resin composition 16 by introducing an ultraviolet curable polymer. The sheet-shaped resin composition 16 may have ultraviolet curability and thermal curability. The sheet-shaped resin composition 16 is further thermally cured by heating after ultraviolet curing, and thereby the reliability of the semiconductor device can be improved.

Examples of the ultraviolet curable polymer include polymers each having a carbon-carbon double bond in a polymer side chain, the main chain, or the main chain terminal as a base polymer.

As the base polymer having a carbon-carbon double bond, one having an acryl-based polymer as a basic backbone is preferable. Examples of the acryl-based polymer include those using, as a main monomer component, one or more of (meth)acrylic acid alkyl esters (for example, linear or branched alkyl esters with the alkyl group having 1 to 30, particularly 1 to 6 carbon atoms, such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nony ester, decyl ester, isodecyl ester, undecyl ester, dodecyl ester, tridecyl ester, tetradecyl ester, hexadecyl ester, octadecyl ester and eicosyl ester) and (meth)acrylic acid cycloalkyl esters (for example, cyclopentyl ester and cyclohexyl ester, etc.). The (meth)acrylic acid ester refers to an acrylic acid ester and/or a methacrylic acid ester, and (meth)has the same meaning throughout the present invention.

Particularly, by using an alkyl group having 7 to 18 carbon atoms as an alkyl group of an acrylic acid alkyl ester which is the constitutional unit of an acryl-based polymer forming the pressure-sensitive adhesive layer of the dicing tape, and using an alkyl group having 1 to 6 carbon atoms as an alkyl group of an acrylic acid alkyl ester which is the constitutional unit of an acryl-based polymer forming the ultraviolet curable polymer contained in the sheet-shaped resin composition, the migration of components between the pressure-sensitive adhesive layer and the sheet-shaped resin composition can be highly suppressed to improve light peelability therebetween, which is preferable.

The acryl-based polymer may contain a unit corresponding to any other monomer component capable of being copolymerized with the (meth)acrylic acid alkyl ester or cycloalkyl ester as necessary for the purpose of modifying cohesive strength, heat resistance and so on. Examples of the monomer component include carboxyl group-containing monomers such as acrylic acid, methacrylic acid, carboxyethyl(meth)acrylate, carboxypentyl(meth)acrylate, itaconic acid, maleic acid, fumaric acid and crotonic acid; acid anhydride monomers such as maleic anhydride and itaconic anhydride; hydroxyl group-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate and (4-hydroxymethylcyclohexyl)-methyl(meth)acrylate; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate and (meth)acryloyloxynaphthalenesulfonic acid; phosphoric acid group-containing monomers such as 2-hydroxyethylacryloyl phosphate; and acrylamide and acrylonitrile. One or more of these monomers capable of being copolymerized can be used. The used amount of the monomer component capable of copolymerization is preferably 40% by weight or less based on total monomer components.

Further, the acryl-based polymer may contain a polyfunctional monomer or the like as a monomer component for copolymerization as necessary for the purpose of crosslinking. Examples of the polyfunctional monomer include hexanediol di(meth)acrylate, (poly)ethylene glycol di(meth)acrylate, (poly)propylene glycol di(meth)acrylate, neopentylglycol di(meth)acrylate, pentaerythrithol di(meth)acrylate, trimethylolpropane tri(meth)acrylate, pentaerythrithol tri(meth)acrylate, dipentaerythrithol hexa(meth)acrylate, epoxy(meth)acrylate, polyester(meth)acrylate and urethane(meth)acrylate. One or more of these polyfunctional monomers can be used. The used amount of the polyfunctional monomer is preferably 30% by weight or less based on total monomer components from the viewpoint of an adhesion property.

The acryl-based polymer is obtained by subjecting a single monomer or monomer mixture of two or more kinds of monomers to polymerization. Polymerization can be carried out by any method such as solution polymerization, emulsion polymerization, bulk polymerization or suspension polymerization. The content of low-molecular weight substances is preferably low from the viewpoint of prevention of contamination of a clean adherend. In this respect, the weight average molecular weight of the acryl-based polymer is preferably 100000 or more, further preferably about 200000 to 3000000, especially preferably about 300000 to 1000000.

The method for introducing a carbon-carbon double bond into the acryl-based polymer is not particularly limited, and various methods can be employed, but it is easy in molecular design to introduce the carbon-carbon double bond into a polymer side chain. Mention is made to, for example, a method in which a monomer having a functional group is copolymerized into an acryl-based polymer beforehand, and thereafter a compound having a functional group that can react with the above-mentioned functional group, and a carbon-carbon double bond is subjected to a condensation or addition reaction while maintaining the ultraviolet curability of the carbon-carbon double bond.

Examples of the combination of these functional groups include a combination of a carboxylic acid group and an epoxy group, a combination of a carboxylic acid group and an aziridyl group and a combination of a hydroxyl group and an isocyanate group. Among these combinations of functional groups, the combination of a hydroxyl group and an isocyanate group is suitable in terms of ease of reaction tracing. The functional group may be present at the side of any of the acryl-based polymer and the aforementioned compound as long as the combination of the functional groups is such a combination that the acryl-based polymer having a carbon-carbon double bond is generated, but for the preferable combination, it is preferred that the acryl-based polymer have a hydroxyl group and the aforementioned compound have an isocyanate group. In this case, examples of the isocyanate compound having a carbon-carbon double bond include metacryloyl isocyanate, 2-metacryloyloxyethyl isocyanate, m-isopropenyl-α,α-dimethylbenzyl isocyanate. As the acryl-based polymer, one obtained by copolymerizing the hydroxy group-containing monomers described previously as an example, ether-based compounds such as 2-hydroxyethylvinyl ether, 4-hydroxybutyl vinyl ether and diethylene glycol monovinyl ether, and so on is used.

The base polymer (particularly acryl-based polymer) having a carbon-carbon double bond can be used alone, but the ultraviolet curable monomer component or oligomer component within the bounds of not deteriorating properties can also be blended. The amount of the radiation curable oligomer component or the like is normally within a range of 30 parts by weight or less, preferably in a range of 0 to 10 parts by weight, based on 100 parts by weight of the base polymer.

A photopolymerization initiator is preferably used in combination with the ultraviolet curable polymer when it is cured by ultraviolet light irradiation. Examples of the photopolymerization initiator include α-ketol-based compounds such as 4-(2-hydroxyethoxy)phenyl(2-hydroxy-2-propyl)ketone, α-hydroxy-α,α′-dimethylacetophenone, 2-methyl-2-hydroxypropiophenone and 1-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morphorinopropane-1; benzoin ether-based compounds such as benzoin ethyl ether, benzoin isopropyl ether and anisoin methyl ether; ketal-based compounds such as benzyldimethylketal; aromatic sulfonyl chloride-based compounds such as 2-naphthalenesulfonyl chloride; photoactive oxime-based compounds such as 1-phenone-1,1-propanedione-2-(o-ethoxycarbonyl)oxime; benzophenone-based compounds such as benzophenone, benzoyl benzoic acid and 3,3′-dimethyl-4-methoxybenzophenone; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone and 2,4-diisopropylthioxanthone; camphorquinone; halogenated ketone; acylphosphinoxide; and acylphosphonate. The blending amount of the photopolymerization initiator is, for example, about 0.05 to 20 parts by weight based on 100 parts by weight of the base polymer such as an acryl-based polymer which forms a pressure-sensitive adhesive.

The ultraviolet curable polymer and the crosslinking agent contained in the pressure-sensitive adhesive for forming the dicing tape can used in combination.

Examples of other constituent material for the sheet-shaped resin composition include a thermoplastic resin and a thermosetting resin.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, saturated polyester resins such as PET and PBT, polyamideimide resin, and fluorine-contained resin. These thermoplastic resins may be used alone or in combination of two or more thereof.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly (p-oxystyrene). These may be used alone or in combination of two or more thereof. Among these phenol resins, phenol Novolak resin and phenol aralkyl resin are particularly preferable, since the sealing reliability can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

The thermal curing-accelerating catalyst of the epoxy resin and the phenol resin is not particularly limited, and a known thermal curing-accelerating catalyst can be appropriately selected and used. The thermal curing-accelerating catalyst may be used either alone or in combination of two or more types. Examples of the thermal curing-accelerating catalyst include an amine based curing accelerator, a phosphorus based curing accelerator, an imidazole based curing accelerator, a boron based curing accelerator, and a phosphorus-boron based curing accelerator.

An inorganic filler may be appropriately incorporated into the sheet-shaped resin composition 16. The incorporation of the inorganic filler makes it possible to confer electric conductance to the sheet, improve the thermal conductivity thereof, and adjust the elasticity.

Examples of the inorganic fillers include various inorganic powders made of the following: a ceramic such as silica, clay, plaster, calcium carbonate, barium sulfate, aluminum oxide, beryllium oxide, silicon carbide or silicon nitride; a metal such as aluminum, copper, silver, gold, nickel, chromium, lead, tin, zinc, palladium or solder, or an alloy thereof; and carbon. These may be used alone or in combination of two or more thereof. Among these, silica, in particular fused silica is preferably used.

The average particle size of the inorganic filler is preferably 0.1 to 30 μm, and more preferably 0.5 to 25 μm. In the present invention, inorganic fillers having different average particle sizes can be combined and used together. The average particle size is obtained by a laser diffraction/scattering particle size distribution analyzer (LA-910 manufactured by HORIBA, Ltd.).

The compounded amount of the inorganic filler is preferably 100 to 1400 parts by weight to 100 parts by weight of the organic resin component. It is especially preferably 230 to 900 parts by weight. When the compounded amount of the inorganic filler is 100 parts by weight or more, the heat resistance and the strength improve. When it is 1400 parts by weight or less, the fluidity can be secured. With this, a decrease of the tackiness and the embedding property can be prevented.

Other additives besides the inorganic filler can be appropriately compounded in the sheet-shaped resin composition 16 as necessary. Examples of other additives include a flame retardant, a silane coupling agent, an ion trapping agent, a pigment such as carbon black. Examples of the flame retardant include antimony trioxide, antimony pentaoxide, and brominated epoxy resin. These may be used alone or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite and bismuth hydroxide. These may be used alone or in combination of two or more thereof. An elastomer component can be added as an additive for adjusting the viscosity to improve the viscosity during curing at high temperature. The elastomer component is not particularly limited as long as it can thicken the resin. However, examples include various acrylic copolymers such as polyacrylic ester; an erastomer having a styrene skeleton such as a polystyrene-polyisobutylene copolymer and a styrene acrylate copolymer; and a rubber copolymer such as a butadiene rubber, a styrene-butadiene rubber (SBR), an ethylene-vinylacetate copolymer (EVA), an isoprene rubber, and acrylonitrile rubber. For the purpose of removing the oxide film on solder at mounting, organic acid may be added.

The viscosity of the sheet-shaped resin composition 16 at 120° C. is preferably 100 Pa·s to 10,000 Pa·s, and more preferably 500 Pa·s to 3,000 Pa·s. When the viscosity is 100 Pa·s or more, large deformation can be suppressed of the shape of the surface at thermal curing. When the viscosity is 10,000 Pa·s or less, insufficient filling of the edge of parts caused by poor fluidity of the resin can be suppressed.

The thickness of the sheet-shaped resin composition 16 (a total thickness when the composition is a multilayer) is not especially limited. However, considering the strength of the resin after the resin is cured and the filling property, the thickness is preferably 10 μm or more and 1,000 μm or less. The thickness of the sheet-shaped resin composition 16 can be appropriately set by considering the width of the space between the chip 20 and the mounting substrate 22.

The sheet-shaped resin composition 16 is produced as follows for example. First, a resin composition solution is produced that is a formation material of the sheet-shaped resin composition 16. As described above, the resin composition, the filler, other various types of additives, etc. are compounded in the resin composition solution.

Next, the resin composition solution is applied on the base separator to have a prescribed thickness to forma coating film. Then, the coating film is dried under a prescribed condition to form the sheet-shaped resin composition 16. The coating method is not especially limited. However, examples include roll coating, screen coating, and gravure coating. For the drying condition, for example, the drying temperature is 70° C. to 160° C. and the drying time is 1 minute to 5 minutes.

(Method of Producing the Dicing Tape-Integrated Sheet-Shaped Resin Composition)

The dicing tape 15 and the sheet-shaped resin composition are pasted together to obtain the dicing tape-integrated sheet-shaped resin composition 14. Pasting can be performed by press bonding for example. At this time, the lamination temperature is not especially limited. However, the lamination temperature is preferably 30° C. to 50° C., and more preferably 35° C. to 45° C. The linear load is not especially limited. However, the linear load is preferably 0.1 kgf/cm to 20 kgf/cm, and more preferably 1 kgf/cm to 10 kgf/cm. Further, the resin composition solution for forming the sheet-shaped resin composition 16 is directly applied on the dicing tape 15 and dried to obtain the dicing tape-integrated sheet-shaped resin composition 14.

[Step D—Pasting Step]

Next, in the pasting step (step D), the first main surface 11a of the wafer 10 with—a supporting member and the sheet-shaped resin composition 16 of the dicing tape-integrated sheet-shaped resin composition 14 are pasted together (see FIG. 3). Pasting can be performed by press bonding for example. At this time, the lamination temperature is not especially limited. However, the lamination temperature is preferably 20° C. to 120° C., and more preferably 40° C. to 100° C. The pressure is not especially limited. However, the pressure is preferably 0.05 MPa to 1.0 MPa, and more preferably 0.1 MPa to 0.8 MPa. Pasting is preferably performed under reduced pressure. When pasting is performed under reduced pressure, the generation of voids at the interface between the wafer 11 and the sheet-shaped resin composition 16 can be suppressed. As a result, the wafer 11 and the sheet-shaped resin composition 16 can be pasted together more suitably. The reduced pressure condition is preferably 5 Pa to 1,000 Pa, and more preferably 10 Pa to 500 Pa. When the step C is performed under the reduced pressure condition, the step C can be performed in a reduced pressure chamber for example.

[Step S—Ultraviolet Curing Step]

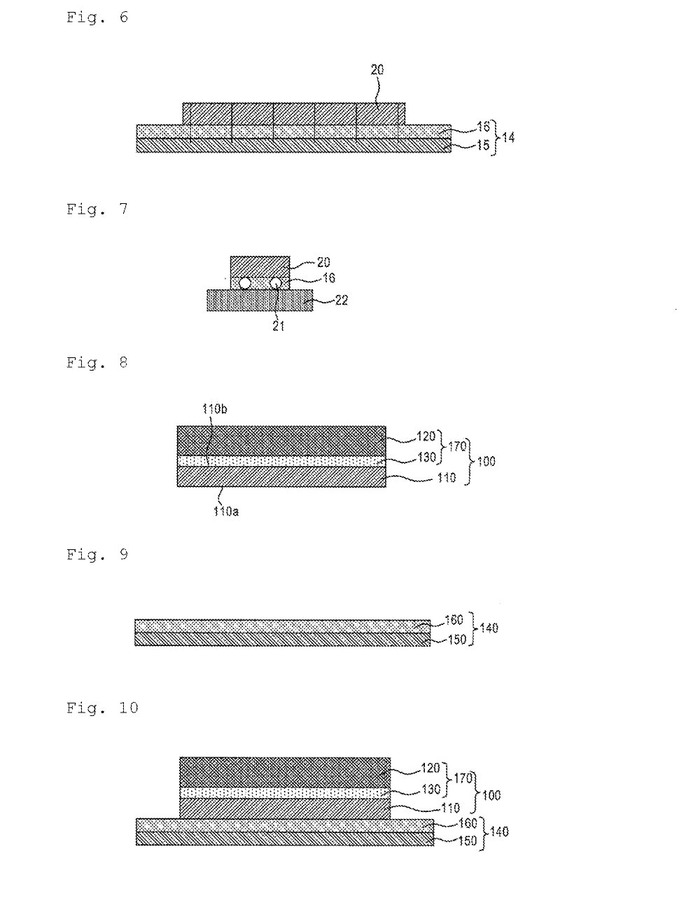

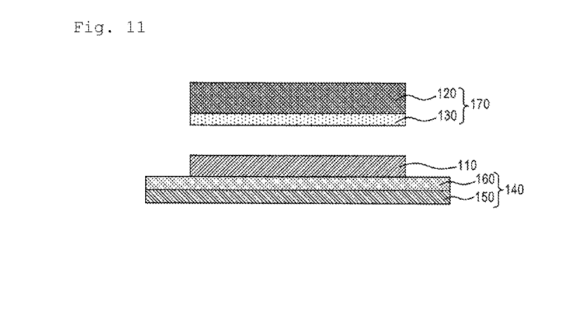

In the ultraviolet curing step (step S), a peripheral part P of the sheet-shaped resin composition 16 is irradiated with ultraviolet light to cure the peripheral part P (see FIG. 4). The peripheral part P is a region of the sheet-shaped resin composition 16 not overlapping with the wafer 11 when a laminate obtained by pasting together the wafer 11 and the sheet-shaped resin composition 16 is viewed in plan. In this manner, even when the residue of the temporary fixing layer 13 remaining on the wafer 11 is cleaned after the supporting member 17 is peeled from the wafer 11, the dissolution of the peripheral part P of the sheet-shaped resin composition 16 caused by a cleaning liquid can be suppressed. The function of the sheet-shaped resin composition in the central part (the filling of the space between the chip and the substrate) can be maintained, and the contamination of other members caused by the dissolution of the sheet-shaped resin composition 16 can be prevented, to efficiently perform the subsequent step.

The sheet-shaped resin composition 16 may be irradiated with ultraviolet light from the wafer 11 side or the dicing tape 15 side. From the viewpoint of efficiently preventing the irradiation of the central part of the sheet-shaped resin composition 16 with ultraviolet light, the sheet-shaped resin composition 16 is preferably irradiated with ultraviolet light from the wafer 11 side. This is because the wafer 11 itself serves as a masking for the central part of the sheet-shaped resin composition 16, which avoids the need for providing a separate masking. When the sheet-shaped resin composition 16 is irradiated with ultraviolet light from the dicing tape 15 side, a masking corresponding to the shape of the wafer may be disposed on the side opposite to the sheet-shaped resin composition 16 of the dicing tape 15, to subject the peripheral part P of the sheet-shaped resin composition 16 to ultraviolet light exposure.

The irradiation dose of the ultraviolet light is not particularly limited as long as the peripheral part P of the sheet-shaped resin composition 16 is cured, but is preferably 50 to 1000 mJ/cm², and more preferably 100 to 600 mJ/cm². By setting the irradiation dose of the ultraviolet light within the above range, the peripheral part P of the sheet-shaped resin composition 16 can be sufficiently cured to such an extent that the peripheral part P is not dissolved by a cleaning liquid, and the high pressure-sensitive adhesion of the sheet-shaped resin composition 16 with the dicing tape caused by excess irradiation heat generation can be prevented.

The ultraviolet curing step may be performed after the pasting step and before the cleaning step to be described later. Therefore, the ultraviolet curing step may be performed not only after the pasting step and before the supporting member peeling step, but also after the supporting member peeling step and before the cleaning step. Among these, the ultraviolet curing step is preferably performed after the pasting step and before the supporting member peeling step from the viewpoint of the masking by the wafer during ultraviolet light irradiation and preventing the fixation of the sheet-shaped resin composition to the temporary fixing material.

[Step E—Supporting member Peeling Step]

Next, in the supporting member peeling step (step E), the supporting member 17 is peeled from the wafer 11 (see FIG. 5). At this time, a force may be applied in the direction of peeling the support 12 from the wafer 11 by suctioning the support 12. When the pressure-sensitive adhesive strength of the temporary fixing layer 13 can be reduced by a predetermined treatment, treatments according to the mechanism of the decrease in the pressure-sensitive adhesive strength of the temporary fixing layer 13 (the above solvent dissolution, ultraviolet curing, thermal curing, thermal foaming, laser firing, and blocking of strong pressure-sensitive adhesion, and the like) are performed, and thereby the supporting member 17 can be promptly peeled by a lighter force. The residue of the temporary fixing layer 13 on the wafer 11 can be reduced, as a result of which the production efficiency of the semiconductor device can be improved.

[Step F—Cleaning Step]

In the cleaning step (step F), the second main surface 11b of the wafer 11 is cleaned to remove the residue of the sheet-shaped resin composition 16 on the wafer 11. The peripheral part P of the sheet-shaped resin composition 16 is cured by ultraviolet light prior to the cleaning step and the dissolution of the peripheral part P caused by the cleaning liquid is suppressed, so that the influence of the cleaning liquid on the central part of the sheet-shaped resin composition 16 can be reduced.

The cleaning liquid (solvent) for cleaning can be appropriately selected depending on the formation material of the temporary fixing layer 13. When the formation material for forming the temporary fixing layer 13 is a polyimide resin, a solvent is preferably used such as N,N-dimethylacetamide (DMAc), N-methyl-2-pyrrolidone (NMP), and N,N-dimethylformamide (DMF). When the formation material for forming the temporary fixing layer 13 is a silicone resin, a solvent is preferably used such as toluene, methylenechloride, and trichloroethane. When the formation material for forming the temporary fixing layer 13 is an aliphatic olefin resin, a solvent is preferably used such as toluene and ethylacetate. When the formation material for forming the temporary fixing layer 13 is a hydrogenated styrene thermoplastic elastomer, a solvent is preferably used such as toluene and ethylacetate. When the formation material for forming the temporary fixing layer 13 is an acrylic resin, a solvent is preferably used such as acetone, methylethylketone, methanol, toluene, and ethylacetate.

[Step G—Dicing step]

Next, the wafer 11 is diced together with the sheet-shaped resin composition 16 to obtain the chip 20 with the sheet-shaped resin composition 16 in the dicing step (Step G) (refer to FIG. 6). Conventionally known blade dicing and laser dicing can be adopted for dicing.

[Step H—Underfill step]

Next, in the underfill step (Step H), the chip 20 with the sheet-shaped resin composition 16 is picked up to be arranged on a mounting substrate 22, the electrodes of the chip 20 (not shown in the drawing) and the electrodes of the mounting substrate 22 (not shown in the drawing) are bonded with the bump (connecting member) 21 interposed therebetween that is formed on the electrodes of the chip 20, and the space between the chip 20 and the mounting substrate 22 is sealed (under-filled) with the sheet-shaped composition 16 (refer to FIG. 7). Specifically, the sheet-shaped resin composition 16 of the chip 20 with the sheet-shaped resin composition 16 is arranged in opposition to the mounting substrate 22, and pressure is applied from the chip 20 with the sheet-shaped resin composition 16 using a flip-chip bonder. With this, the electrodes of the chip 20 and the electrodes of the mounting substrate 22 are bonded with the bump 21 interposed therebetween that is formed on the electrodes of the chip 20, and the space between the chip 20 and the mounting substrate 22 is sealed (under-filled) with the sheet-shaped composition 16. The bonding temperature is preferably 50° C. to 300° C., and more preferably 100° C. to 280° C. The bonding pressure is preferably 0.02 MPa to 10 MPa, and more preferably 0.05 MPa to 5 MPa.

Below, preferred examples of the present invention are explained in detail. The materials, the compounding amounts, etc. that are described in the examples are not for limiting the key points of this invention to these examples, unless described specifically as a limitation. “Parts” in these examples mean “parts by weight”.

### Example 1

### Production of Sheet-shaped Resin Composition

Each of the following components (a) to (g) was dissolved or dispersed in methyl ethyl ketone to obtain a resin composition solution having a solid content concentration of 23.6% by weight.
(a) Ultraviolet curable acrylic polymer (*): 100 parts
(b) Epoxy resin 1 (trade name “Epikote 1004” manufactured by Japan Epoxy Resins Co., Ltd.): 24 parts
(c) Epoxy resin 2 (trade name “Epikote 828” manufactured by Japan Epoxy Resins Co., Ltd.): 24 parts
(d) Phenol resin (trade name “Milex XLC-4L” manufactured by Mitsui Chemicals, Inc.): 51 parts
(e) Spherical silica (trade name “SO-25R” manufactured by Admatechs Company Limited): 257 parts
(f) Organic acid (trade name “Ortho-Anisic Acid” manufactured by Tokyo Chemical Industry Co., Ltd.): 10 parts
(g) Imidazole catalyst (trade name “2PHZ-PW” manufactured by Shikoku Chemicals Corporation): 0.5 parts

(*) An ultraviolet curable acrylic polymer was prepared as follows. First, 100 parts of butyl acrylate (hereinafter, referred to as “BA”), 78 parts of ethyl acrylate (hereinafter, referred to as “EA”), 40 parts of 2-hydroxyethyl acrylate (hereinafter, referred to as “HEA”), 0.3 parts of benzoyl peroxide, and 65 parts of toluene were charged to a reactor equipped with a cooling tube, a nitrogen gas introducing tube, a thermometer, and a stirrer. These were subjected to a polymerization treatment in a nitrogen gas flow at 61° C. for 6 hours to obtain an acrylic polymer A having a weight average molecular weight of 500,000.

To the acrylic polymer A was added 44 parts (82 mol % based on HEA) of 2-methacryloyloxyethylisocyanate (hereinafter, referred to as “MOI”), and these were subjected to an addition reaction treatment in an air flow at 50° C. for 48 hours to obtain an acrylic polymer A′.

Next, 8 parts of a polyisocyanate compound (trade name “Coronate L” manufactured by Nippon Polyurethane Industry Co., Ltd.) and 5 parts of a photopolymerization initiator (trade name “Irgacure 651” manufactured by Chiba Specialty Chemicals Corporation) were added to 100 parts of the acrylic polymer A′ to produce an ultraviolet curable acrylic polymer.

The prepared resin composition solution was applied onto a release-treated film (peeling liner) including a silicone release-treated polyethylene terephthalate film having a thickness of 50 μm, and then dried at 130° C. for 2 minutes. In this manner, a circular sheet-shaped resin composition A having a thickness of 20 μm and a diameter of 230 mm was produced.

<Production of Dicing Tape>

To a reactor equipped with a cooling tube, a nitrogen gas introducing tube, a thermometer, and a stirrer were charged 88.8 parts of 2-ethylhexyl acrylate (hereinafter, referred to as “2EHA”), 11.2 parts of 2-hydroxyethyl acrylate (hereinafter, referred to as “HEA”), 0.2 parts of benzoyl peroxide, and 65 parts of toluene. These were subjected to a polymerization treatment in a nitrogen gas flow at 61° C. for 6 hours to obtain an acrylic polymer A having a weight average molecular weight of 850,000. The weight average molecular weight is as follows. The molar ratio of 2EHA to HEA was set to 100 mol:20 mol.

To the acrylic polymer A was added 12 parts (80 mol % based on HEA) of 2-methacryloyloxyethylisocyanate (hereinafter, referred to as “MOI”). These were subjected to an addition reaction treatment in an air flow at 50° C. for 48 hours to obtain an acrylic polymer A′.

Next, 8 parts of a polyisocyanate compound (trade name “Coronate L” manufactured by Nippon Polyurethane Industry Co., Ltd.) and 5 parts of a photopolymerization initiator (trade name “Irgacure 651” manufactured by Chiba Specialty Chemicals Corporation) were added to 100 parts of the acrylic polymer A′ to produce a pressure-sensitive adhesive solution.

The pressure-sensitive adhesive solution prepared above was applied onto a silicone-treated surface of a PET peeling liner, and cross-linked by heating at 120° C. for 2 minutes to form a pressure-sensitive adhesive layer having a thickness of 10 μm. Then, a polyolefin film having a thickness of 100 μm was pasted on the surface of the pressure-sensitive adhesive layer to produce a laminate. Then, the laminate was stored at 50° C. for 24 hours, and a portion on which the sheet-shaped adhesion composition would be pasted was then previously irradiated with ultraviolet light (300 mJ/cm²) to produce a dicing tape A according to the present Example.

<Production of Dicing Tape-Integrated Sheet-shaped Resin Composition>

The sheet-shaped resin composition A was pasted on the pressure-sensitive adhesive layer A of the dicing tape A using a hand roller to produce a dicing tape-integrated sheet-shaped resin composition A.

<Production of Temporary Fixing Layer>

One part of a polyisocyanate compound (trade name “Coronate L” manufactured by Nippon Polyurethane Industry Co., Ltd.) and 2 parts of a photopolymerization initiator (trade name “Irgacure 651” manufactured by Chiba Specialty Chemicals Corporation) were added to 100 parts of the acrylic polymer A′ to produce a pressure-sensitive adhesive solution. A temporary fixing layer A having a thickness of 100 μm was obtained using the pressure-sensitive adhesive solution.

[Process Evaluation]

The temporary fixing layer A was pasted to a silicon wafer having a diameter of 195 mm and a thickness of 725 μm. Pasting was performed at a temperature of 90° C. and a pressure of 0.1 MPa by roll lamination. A pedestal (a silicon wafer having a diameter of 200 mm and a thickness 726 μm) was pasted as a support to the remaining surface of the temporary fixing layer A to which the silicon wafer was pasted. At this time, pasting was performed at a temperature of 120° C. and a pressure of 0.3 MPa. The temporary fixing layer A was thereby fixed to the pedestal. A wafer with—a supporting member was thereby obtained in which the pedestal, the temporary fixing layer A, and the silicon wafer were sequentially laminated.

The silicon wafer of the obtained wafer with a supporting member was subjected to back grinding until a wafer thickness was adjusted to 50 μm to form a ground laminate. The ground laminate was laminated on the dicing tape-integrated sheet-shaped resin composition A under conditions of 80° C., 0.2 MPa, and 10 mm/s.

The ground laminate was irradiated with ultraviolet light at an irradiation dose of 450 mJ/cm² from the wafer side to cure the peripheral part of the sheet-shaped resin composition.

Then, the pedestal was placed below so that the pressure-sensitive adhesive layer A was dipped in methyl ethyl ketone (MEK) for 30 seconds, and the wafer was took out. Then, the pedestal was peeled using tweezers.

Furthermore, the exposed surface of the wafer was cleaned with MEK (50 mL×3 times) using a waste cloth, and finally dried in a drier at 100° C. for 30 minutes.

The peripheral part of the sheet-shaped resin composition at this time was observed with an optical microscope (100 times), and the presence or absence of the dissolution of the sheet-shaped resin composition was confirmed.

### Comparative Example 1

Process evaluation was performed in the same manner as in Example 1 except that the peripheral part of the sheet-shaped resin composition was not irradiated with ultraviolet light.

TABLE 1

| | Ultraviolet light | | |
|---|---|---|---|
| | irradiation to | Dissolution of | |
| | peripheral part | peripheral part | |
| | of sheet-shaped | of sheet-shaped | |
| | resin composition | resin composition | Evaluation |
| Example 1 | Presence | Absence | ∘ |
| Comparative | Absence | Presence | x |
| Example 1 | | | |

In Example 1, it is found that the dissolution of the peripheral part of the sheet-shaped resin composition was suppressed, and a reliable semiconductor device can be manufactured at a high yield ratio. On the other hand, in Comparative Example 1, it is found that, in addition to the peripheral part of the sheet-shaped resin composition, the partial dissolution of the central part was observed, and the function of the sheet-shaped resin composition may be impaired.

### REFERENCE CHARACTERS LIST

10 wafer with—a supporting member
11 wafer
11a first main surface (of wafer 11)
11b second main surface (of wafer 11)
12 support
13 temporary fixing layer
14 dicing tape-integrated sheet-shaped resin composition
15 dicing tape
16 sheet-shaped resin composition
17 supporting member
20 chip
22 mounting substrate

1. A method for manufacturing a semiconductor device, the method comprising:
a step A of preparing a wafer having a first main surface having at least a connecting member formed thereon;
a step B of pasting together a second main surface opposite to the first main surface of the wafer and a supporting member including a support and a temporary fixing layer formed on the support with the temporary fixing layer interposed between the second main surface and the supporting member, to form a wafer with a supporting member;
a step C of preparing a dicing tape-integrated sheet-shaped resin composition including a dicing tape and an ultraviolet curable sheet-shaped resin composition laminated on the dicing tape;
a step D of pasting together the first main surface of the wafer of the wafer with a supporting member and the sheet-shaped resin composition of the dicing tape-integrated sheet-shaped resin composition;
a step E of peeling the supporting member from the wafer after the step D;
a step F of cleaning the second main surface of the wafer after the step E; and
a step S of irradiating a peripheral part of the sheet-shaped resin composition with ultraviolet light to cure the peripheral part after the step D and before the step F, the peripheral part not overlapping with the wafer in a plan view.

2. The method for manufacturing a semiconductor device according to claim 1, wherein the irradiation with ultraviolet light is conducted from the wafer side in the step S.

3. The method for manufacturing a semiconductor device according to claim 1, wherein the step S is performed after the step D and before the step E.

4. The method for manufacturing a semiconductor device according to claim 1, further comprising a step G of dicing the wafer together with the sheet-shaped resin composition after the step F to obtain a chip with a sheet-shaped resin composition.

5. The method for manufacturing a semiconductor device according to claim 1, further comprising a step H of disposing the chip with a sheet-shaped resin composition on a mounting substrate after the step G, and sealing a space between the chip and the mounting substrate with the sheet-shaped composition while bonding the connecting member included in the chip and an electrode included in the mounting substrate.

6. The method for manufacturing a semiconductor device according to claim 1, wherein the step D is performed under reduced pressure.

7. A sheet-shaped resin composition used in the method for manufacturing a semiconductor device according to claim 1.

8. A dicing tape-integrated sheet-shaped resin composition used in the method for manufacturing a semiconductor device according to claim 1.
